(19) United States
(12) Patent Application Publication
(10) Pub. No.: US 2005/0020148 A1
(43) Pub. Date: Jan. 27, 2005

(54) Integrated network-port socket and physical-layer device and main board incorporating the same

(76) Inventors: Hsi-Chih Peng, Taipei (TW); Camille Lee, Taipei (TW)

Correspondence Address: MADSON & METCALF;GATEWAY TOWER WEST, SUITE 900, 15 WEST SOUTH TEMPLE, SALT LAKE CITY, UT, 84101, US

(21) Appl. No.: 10/894,809

(22) Filed: Jul. 20, 2004

(30) Foreign Application Priority Data
Jul. 22, 2003 (TW) 092213378

(51) Int. Cl. G01R 31/02

(52) U.S. Cl. 439/894

(57) ABSTRACT

A signal-line socket includes a housing, a circuit board, a socket terminal and a signal pin. The housing has a socket hole for receiving a plug of an external signal line. The circuit board is disposed in the housing and has room for mounting thereon an analog circuit chip. The socket terminal is electrically connected to the circuit board and exposed from the socket hole to be electrically connected to the plug of the external signal line for connecting the network signal line to the analog circuit chip. The signal pin is electrically connected to the circuit board and exposed from the housing to be electrically connected to a main board of a computer for connecting the analog circuit chip to the main board of the computer.

### FIELD OF THE INVENTION

The present invention relates to a socket structure, and particularly to a network-port socket structure for use in a computer host to communicate with the external. The present invention also relates to a main board having such socket structure.

### BACKGROUND OF THE INVENTION

FIG. 1(a) is a schematic diagram illustrating the relative locations of a central processing unit (CPU) 10, a core logic unit 11 including a north bridge chip 111 and a south bridge chip 112, a high-speed Ethernet socket 12 and a physical layer (PHY) chip 13, all of which are mounted on a main board 1. The high-speed Ethernet socket 12 is also usually referred to as an RJ-45 socket. A conventional high-speed Ethernet socket 12 shown in FIG. 1(b) comprises a high-voltage resistant capacitor 121 and a transformer 122. The PHY chip 13 is conventionally designed to be distant from the CPU 10 as far as possible for avoiding interference of heat and noise generated during the operation of the CPU 10. Accordingly, the distance between the PHY chip 13 and the high-speed Ethernet socket 12 adjacent to the CPU 10 is kept long, and thus a trace 131 for connecting the PHY chip 13 to the high-speed Ethernet socket 12 needs to be long as well. Since the trace 131 is used as a transmission line for transmitting analog signals with high frequency, the great length thereof is disadvantageous for impedance control due to possible return loss and insertion loss. In addition, the switching power supply (not shown) disposed on the main board may interfere with the high-frequency analog signals transmitted on the main board.

### SUMMARY OF THE INVENTION

The present invention provides a network-port socket structure, which is close to the PHY chip so as to minimize the return loss and insertion loss.

The present invention also provides a main board of a computer system, having closely disposed network-port socket and PHY chip so as to minimize the return loss and insertion loss.

In accordance with a first aspect of the present invention, there is provided a signal-line socket. The signal-line socket comprises a housing, a circuit board, a socket terminal and a signal pin. The housing has a socket hole for receiving a plug of an external signal line. The circuit board is disposed in the housing and has room for mounting thereon an analog circuit chip. The socket terminal is electrically connected to the circuit board and exposed from the socket hole to be electrically connected to the plug of the external signal line for connecting the external signal line to the analog circuit chip. The signal pin is electrically connected to the circuit board and exposed from the housing to be electrically connected to a main board of a computer for connecting the analog circuit chip to the main board of the computer.

In an embodiment, the signal pin is electrically connected to a chipset disposed on the main board of the computer via a digital signal line.

In an embodiment, the signal-line socket is a network-port socket, and the digital signal line, analog circuit chip and external signal line are a media independence interface signal line, a network physical layer circuit chip and a network signal line, respectively.

In an embodiment, the signal-line socket is an IEEE 1394 signal-line socket, and the digital signal line, analog circuit chip and external signal line are an IEEE 1394 digital signal line, an IEEE 1394 control chip and an IEEE 1394 signal line, respectively.

In an embodiment, the signal-line socket is an audio signal line socket, and the digital signal line, analog circuit chip and external signal line are an audio digital signal line, an audio analog circuit chip and an audio signal line, respectively.

In an embodiment, the signal-line socket further comprises a high-voltage resistant capacitor and a transformer disposed on the circuit board.

In accordance with a second aspect of the present invention, there is provided a network-port socket. The network-port socket comprises a housing, a circuit board, a socket terminal and a signal pin. The housing has a socket hole for receiving a plug of a network signal line. The circuit board is disposed in the housing and having room for mounting thereon a physical layer circuit. The socket terminal is electrically connected to the circuit board and exposed from the socket hole to be electrically connected to the plug of the network signal line for connecting the network signal line to the physical layer circuit. The signal pin is electrically connected to the circuit board and exposed from the housing to be electrically connected to a main board of a computer for connecting the physical layer circuit to the main board of the computer.

Preferably, the network-port socket is an RJ-45 socket.

In an embodiment, the network-port socket further comprises a high-voltage resistant capacitor and a transformer disposed on the circuit board.

In an embodiment, the signal pin is electrically connected to a chipset disposed on the main board of the computer via a media independent interface (MII) for transmitting digital signals.

In an embodiment, the signal pin is electrically connected to the chipset via reduced media independent interface (RMII) or source synchronous media independent interface (SSMII).

In an embodiment, the signal pin is electrically connected to the south bridge chip disposed on the main board of the computer.

In accordance with a third aspect of the present invention, there is provided a main board of a computer. The main board comprises a main body, a socket, a central processing unit, a core logic unit and an analog circuit chip. The socket is disposed on the main body for receiving a plug of an external signal line. The central processing unit and the core logic unit are disposed on the main body. The analog circuit chip is disposed on the main body and electrically connected between the socket and the core logic unit, wherein the analog circuit chip is in the vicinity of or inside the socket to be kept at least a certain distance away from the central processing unit.

In an embodiment, the analog circuit chip and the socket are a network physical layer circuit chip and a network-port socket, respectively.

In an embodiment, the analog circuit chip, and the socket are an IEEE 1394 control chip and an IEEE 1394 signal line socket, respectively.

In an embodiment, the analog circuit chip and the socket are an audio analog circuit chip and an audio signal line socket, respectively.

The present invention will become more readily apparent to those ordinarily skilled in the art after reviewing the following detailed description and accompanying drawings, in which:

### BRIEF DESCRIPTION OF THE DRAWINGS

FIG. 1(a) is a schematic diagram illustrating the arrangement of networking-related components on a main board according to prior art;

FIG. 1(b) is a schematic cross-sectional diagram of a high-speed Ethernet socket according to prior art;

FIG. 2(a) is a schematic diagram illustrating the arrangement of networking-related components on a main board according to a preferred embodiment of the present invention;

FIG. 2(b) is a schematic diagram illustrating the arrangement of networking-related components on a main board according to another preferred embodiment of the present invention; and

FIGS. 3(a) and 3(b) are schematic cross-sectional diagrams illustrating two examples of the integrated network-port sockets of FIG. 2(b).

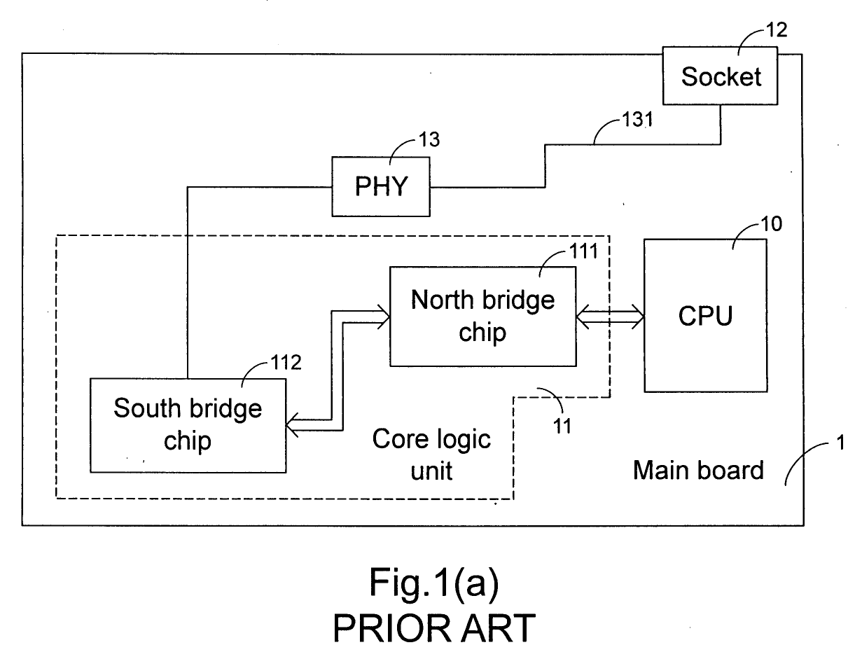

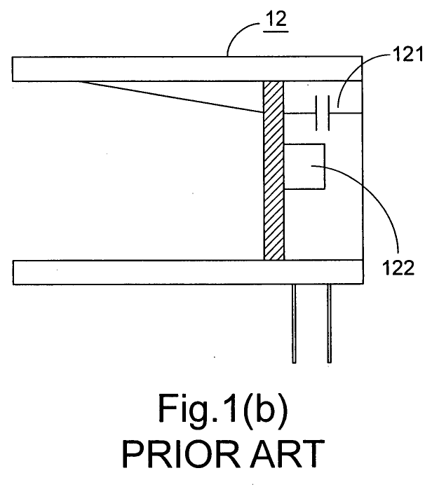

### DETAILED DESCRIPTION OF THE PREFERRED EMBODIMENT

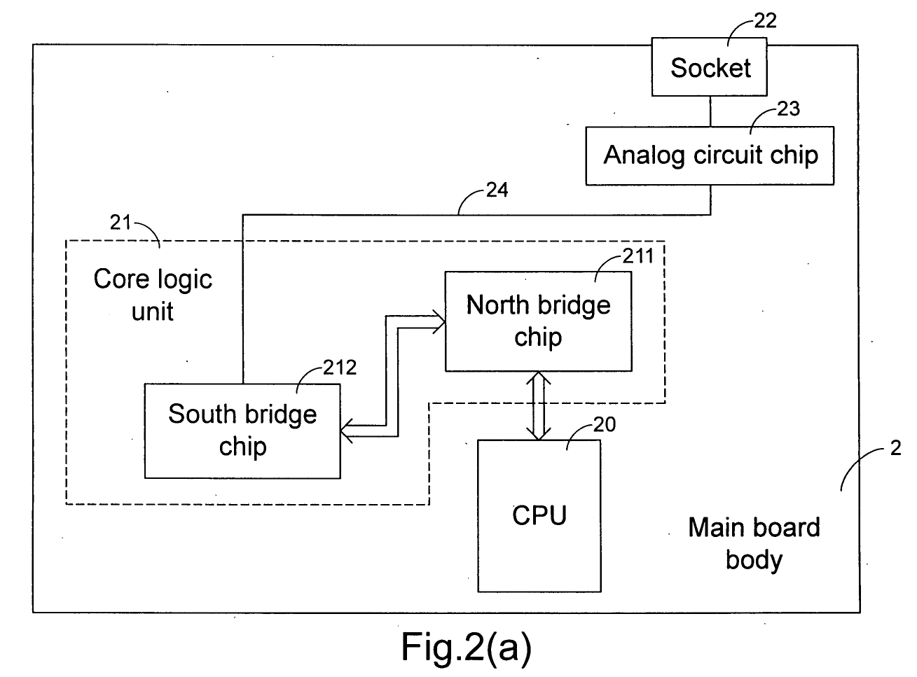

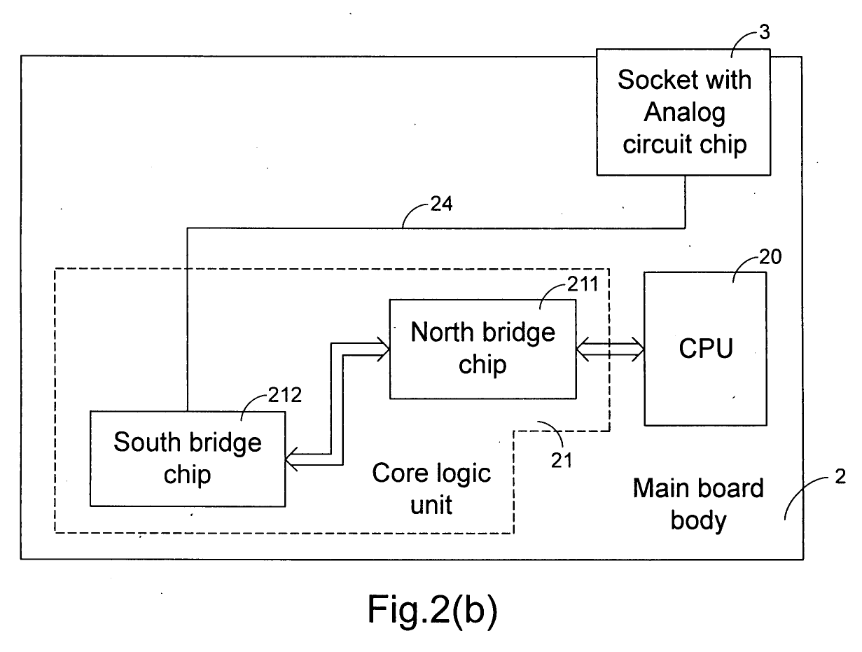

Please refer to FIG. 2(a). The main board comprises a central processing unit (CPU) 20, a core logic unit 21 including a north bridge chip 211 and a south bridge chip 212, a socket 22 for receiving therefrom an external signal line and an analog circuit control chip 23 communicating with the socket 22 via an analog signal line 25 but communicating with the south bridge chip 212 via a digital signal line 24, all of which are disposed on a main body 2 of the main board.

In this embodiment, the analog circuit chip 23 is disposed in the vicinity of the socket 22 for minimizing the return loss and insertion loss while being kept at least a certain distance away from the CPU 20 to prevent from interfering with the high-frequency analog signals transmitted on the main board. For example, the distance between the analog circuit chip 23 and the CPU 20 could be greater than 100 or at least 10 times of the distance between the analog circuit chip 23 and the socket 22.

Since the analog circuit chip 23 is designed to be properly distant from the CPU 20, the interference resulting from heat and noise generated during the operation of the CPU 20 can be effectively avoided: Moreover, since the analog circuit chip 23 is disposed closely next to the socket 22, the trace serving as the analog signal line is largely shortened and thus the return loss and the insertion loss produced during transmission of analog signals with high frequency can be minimized. Moreover, the switching power supply (not shown) disposed on the main board will almost no longer interfere with the high-frequency analog signals transmitted on the main board. Although the digital signal line 24 might be lengthened due to the reduction of length of the analog signal trace 25, the transmission quality of the digital signal line 24 is hardly influenced because of the digital transmission feature.

In the above embodiment, the socket 22 can be a high speed Ether network-port socket, e.g. an RJ-45 socket, and the analog circuit chip 23 can be a PHY chip. The digital signal line 24, accordingly, is preferably a media independent interface (MII). Since the typical media independent interface requires 16 pins which is much larger than the pin number of the general network-port socket, the media independent interface is preferably modified to comply with the digital signal transmission specification requiring 5 or 6 signal pins. For example, a reduced media independent interface (RMII) or a source synchronous media independent interface (SSMII) is suitable to be used here as the digital signal line 24.

Alternatively, the socket 22 can be an IEEE1394 signal line socket, and the analog circuit chip 23 can be an IEEE1394 control chip. The digital signal line 24, accordingly, is an IEEE1394 signal line. Further, the socket 22 can be an audio signal line socket, and the analog circuit chip 23 can be an audio analog circuit chip. The digital signal line 24, accordingly, is an audio signal line.

Please refer to FIG. 2(b), which is a schematic diagram illustrating the arrangement of networking-related components on a main board according to another preferred embodiment of the present invention. In this embodiment, the analog circuit chip is integrated into the socket to construct a novel socket structure 3. By this way, no analog signal trace is required and the analog circuit chip is kept away from the CPU 20. Therefore, the return loss and the insertion loss produced during transmission of analog signals with high frequency can be eliminated, and the switching power supply (not shown) disposed on the main board will no longer interfere with the high-frequency analog signals transmitted on the main board. Moreover, the interference resulting from heat and noise generated during the operation of the CPU 20 can be effectively avoided.

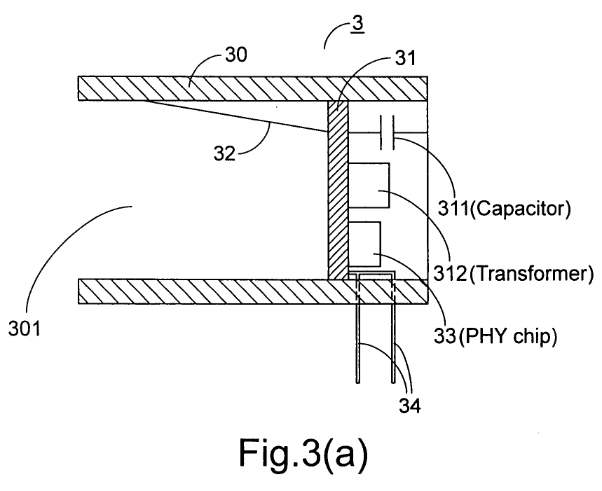

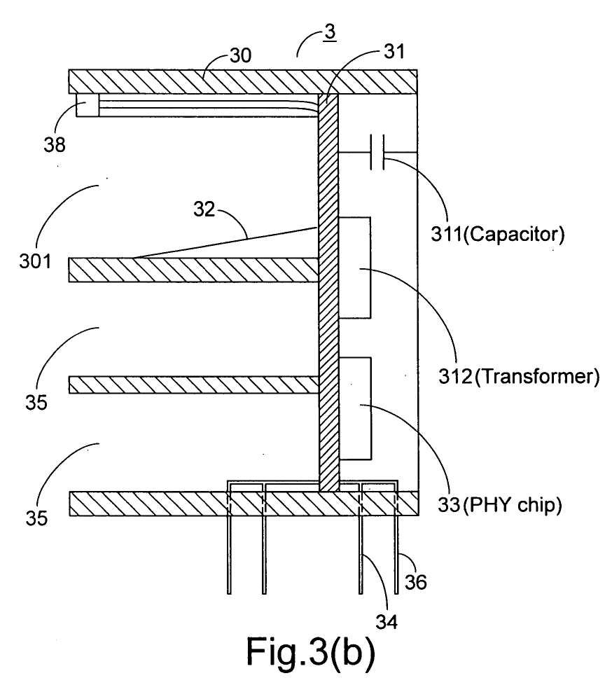

An example of the integrated socket of FIG. 2(b) is illustrated in FIG. 3(a). A PHY chip is given as an example of the analog circuit chip to be incorporated into a network-port socket to form the socket 3. Described in detail, the integrated network-port socket 3 comprises a circuit board 31, a high-voltage resistant capacitor 311, a transformer 312 and a PHY chip 33 disposed on the circuit board 31, and a socket terminal 32 and a plurality of signal pins 34 electrically connected to the circuit board 31. The circuit board 31, the socket terminal 32 and the PHY chip 33 are disposed in the housing 30 of the socket 3. The signal pins 34 are electrically connected to the circuit board 31 and protruding from the housing 30 to be in electrical connection with the south bridge chip 212 disposed on the main board body 2. When required, the plug of an external signal line (not shown) can be inserted into the socket hole 301 exposed from the housing 30 to be electrically connected with the socket terminal 32. Via the socket terminal 32 electrically connected to the circuit board 31, the external signal line can communicate with the PHY chip 33 mounted on the circuit board 31.

A further example of an integrated network-port socket is illustrated in FIG. 3(b). In this embodiment, the socket 3, in addition to the network-port socket unit, incorporates thereinto two universal serial bus (USB) socket units 35. The housing 30 and the circuit board 31 are common to the three socket units, and the high-voltage resistant capacitor 311, the transformer 31, the socket terminal 32 and the PHY chip 33 are mounted on the circuit board. Since the area of the circuit board 31 is enlarged, ample room is available for additionally mounting thereon the PHY chip 33. The socket 3 can be further provided with a light-emitting diode (LED) indicator 38 to indicate the working status of the PHY chip 33. For the sake of limited pin number, the signal pin 36 for transmitting the signal indicating the working status of the PHY chip 33 to the LED indicator 38 can be used for transmitting digital signals outputted from the PHY chip 33 without additional signal pin.

The concept and technical principle of the present invention can be applied to other signal-line sockets for communicating external signal lines with corresponding analog circuit chips for minimizing the interference between the analog signal line and the analog circuit chip. Further, by shortening or eliminating the trace between the analog circuit chip and the signal-line socket according to the present invention, the return loss and the insertion loss produced during transmission of analog signals with high frequency and the interference effect resulting from the switching power supply can be minimized.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A signal-line socket, comprising:
a housing having a socket hole for receiving a plug of an external signal line;
a circuit board disposed in said housing and having room for mounting thereon an analog circuit chip;
a socket terminal electrically connected to said circuit board and exposed from said socket hole to be electrically connected to the plug of the external signal line for connecting said external signal line to said analog circuit chip; and
a signal pin electrically connected to said circuit board and exposed from said housing to be electrically connected to a main board of a computer for connecting said analog circuit chip to the main board of the computer.

2. The signal-line socket according to claim 1 wherein said signal pin is electrically connected to a chipset disposed on the main board of the computer via a digital signal line.

3. The signal-line socket according to claim 2 being a network-port socket, and the digital signal line, analog circuit chip and external signal line being a media independence interface signal line, a network physical layer circuit chip and a network signal line, respectively.

4. The signal-line socket according to claim 2 being an IEEE 1394 signal-line socket, and the digital signal line, analog circuit chip and external signal line being an IEEE 1394 digital signal line, an IEEE 1394 control chip and an IEEE 1394 signal line, respectively.

5. The signal-line socket according to claim 2 being an audio signal line socket, and the digital signal line, analog circuit chip and external signal line being an audio digital signal line, an audio analog circuit chip and an audio signal line, respectively.

6. The signal-line socket according to claim 1 further comprising a high-voltage resistant capacitor and a transformer disposed on said circuit board.

7. A network-port socket, comprising:
a housing having a socket hole for receiving a plug of a network signal line;
a circuit board disposed in said housing and having room for mounting thereon a physical layer circuit;
a socket terminal electrically connected to said circuit board and exposed from said socket hole to be electrically connected to the plug of the network signal line for connecting the network signal line to said physical layer circuit; and
a signal pin electrically connected to said circuit board and exposed from said housing to be electrically connected to a main board of a computer for connecting said physical layer circuit to the main board of the computer.

8. The network-port socket according to claim 7 being an RJ-45 socket.

9. The network-port socket according to claim 7 further comprising a high-voltage resistant capacitor and a transformer disposed on said circuit board.

10. The network-port socket according to claim 7 wherein said signal pin is electrically connected to a chipset disposed on the main board of the computer via a media independent interface (MII) for transmitting digital signals.

11. The network-port socket structure according to claim 7 wherein said signal pin is electrically connected to the chipset via reduced media independent interface (RMII) or source synchronous media independent interface (SSMII).

12. The network-port socket according to claim 7 wherein said signal pin is electrically connected to the south bridge chip disposed on the main board of the computer.

13. A main board of a computer, comprising:
a main body;
a socket disposed on said main body for receiving a plug of an external signal line;
a central processing unit disposed on said main body;
a core logic unit disposed on said main body; and
an analog circuit chip disposed on said main body and electrically connected between said socket and said core logic unit, wherein said analog circuit chip is in the vicinity of or inside said socket to be kept at least a certain distance away from said central processing unit.

14. The main board according to claim 13 wherein said analog circuit chip and said socket are a network physical layer circuit chip and a network-port socket, respectively.

15. The main board according to claim 13 wherein said analog circuit chip, and said socket are an IEEE 1394 control chip and an IEEE 1394 signal line socket, respectively.

16. The main board according to claim 13 wherein said analog circuit chip and said socket are an audio analog circuit chip and an audio signal line socket, respectively.
